(19) United States
(12) Patent Application Publication
(10) Pub. No.: US 2013/0265718 A1
(43) Pub. Date: Oct. 10, 2013

(54) HEAT DISSIPATION CIRCUIT AND ELECTRONIC DEVICE HAVING THE SAME

(71) Applicant: TAO WANG, Shenzhen City (CN)

(72) Inventor: TAO WANG, Shenzhen City (CN)

(21) Appl. No.: 13/652,523

(22) Filed: Oct. 16, 2012

(30) Foreign Application Priority Data
Apr. 9, 2012 (CN) 201210100941.3

(51) Int. Cl. H05K 7/20

(52) U.S. Cl. 361/695; 361/688

(57) ABSTRACT

An electronic device includes a power supply, a heat generating module, a detecting module, a switching module presetting a predetermined voltage, and a heat dissipation module. The heat generating module is powered by the power supply to generate heat. The detecting module detects the heat of the heat generating module and generates a control voltage variable with the heat of the heat generating module. The switching module establishes the electrical connection between the power supply and the heat dissipation module when the control voltage is smaller than the predetermined voltage and generates a working voltage variable with the control voltage. The heat dissipation module is powered by the working voltage to dissipate the heat of the heat generating module with different heat dissipation efficiency. The heat dissipation efficiency is variable with the working voltage.

### BACKGROUND

1. Technical Field

The present disclosure relates to electronic devices, particularly to an electronic device with a heat dissipation circuit.

2. Description of Related Art

Electronic device, such as portable computer, includes a heat dissipation circuit for dissipating heat generated by a heat generating element. The heat dissipation circuit includes a detecting unit, a pulse width modulation (PWM) chip, a transistor, and a fan. The detecting unit adjacent to the heat generating element detects heat from the heat generating element and generates a detecting signal. The PWM chip adjusts the duty cycle of the pulse voltage in response to the detecting signal. The transistor is turned on to establish the electrical connection between the PWM chip and the fan when the pulse voltage is in a high logic voltage. The fan adjacent to the heat generating element rotates when the transistor is turned on. However, the rotating speed of the fan is unchangeable and energy is wasted.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIG. 1 is a block diagram of an electronic device in accordance with one embodiment.

FIG. 2 is a circuit diagram of the electronic device of FIG. 1 in accordance with one embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

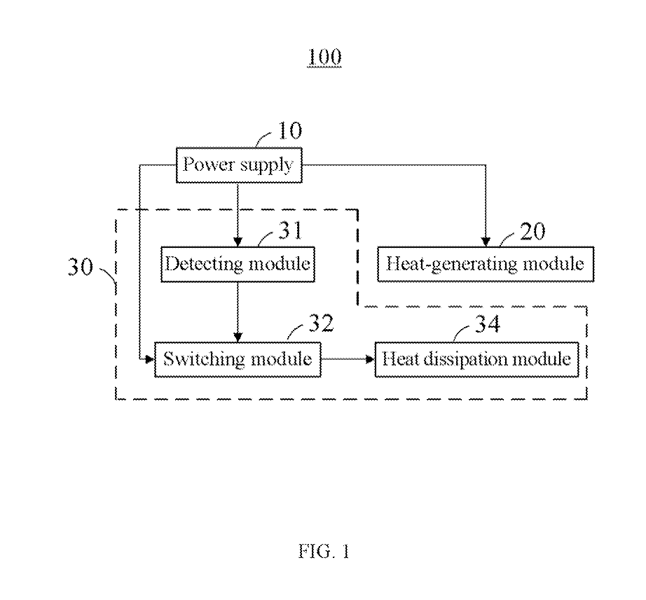

Referring to FIG. 1, an electronic device 100 of one embodiment of the present disclosure is shown. The electronic device 100 includes a power supply 10, a heat generating module 20, and a heat dissipation circuit 30. In the embodiment, the electronic device 100 can be a computer, or a TV, for example.

The power supply 10 provides a supply voltage to the heat generating module 20 and the heat dissipation circuit 30. In the embodiment, the supply voltage is 5V.

The heat generating module 20 is powered by the supply voltage 10 to generate heat based on the supply voltage. In the embodiment, the heat generating module 20 is an electronic component having large power consumption.

The heat dissipation circuit 30 is powered by the supply voltage to dissipate the heat from the heat generating element 20. The heat dissipation circuit 30 includes a detecting module 31, a switching module 32, and a heat dissipation module 34.

The detecting module 31 is disposed adjacent to the heat generating module 20 and detects the heat from the heat generating module 20 to output a control voltage variable with the detected heat.

The switching module 32 is connected between the power supply 10 and the heat dissipation module 34, and presets a predetermined voltage. When the control voltage is smaller than the predetermined voltage, the switching module 32 establishes the electrical connection between the power supply 10 and the heat dissipation module 34 to generate a working voltage variable with the control voltage. When the control voltage is larger than or equal to the predetermined voltage, the switching module 32 cuts off the electrical connection between the power supply 10 and the heat dissipation module 34 and stops generating working voltage. The working voltage varies with the control voltage. In the embodiment, the working voltage is changed linearly with the control voltage; the predetermined voltage is less than the voltage of the power supply 10.

The heat dissipation module 34 is disposed adjacent to the heat generating module 20. The heat dissipation module 34 is powered by the working voltage to dissipate the heat generated by the heat generating module 20 with different heat dissipation efficiencies. In the embodiment, the heat dissipation efficiency is changed linearly with the working voltage. The heat dissipation module 34 is a fan, the fan generates airflow towards the heat generating module 20 and dissipates the heat of the heat generating module 20 accordingly, and the rotation speed of the fan is variable with the working voltage. If the rotation speed of the fan increases, the heat dissipation efficiency of the heat dissipation module 34 also increases. If the rotation speed of the fan decreases, the heat dissipation efficiency of the heat dissipation module 34 also decreases. Preferably, the rotation speed of the fan is changed linearly with the working voltage.

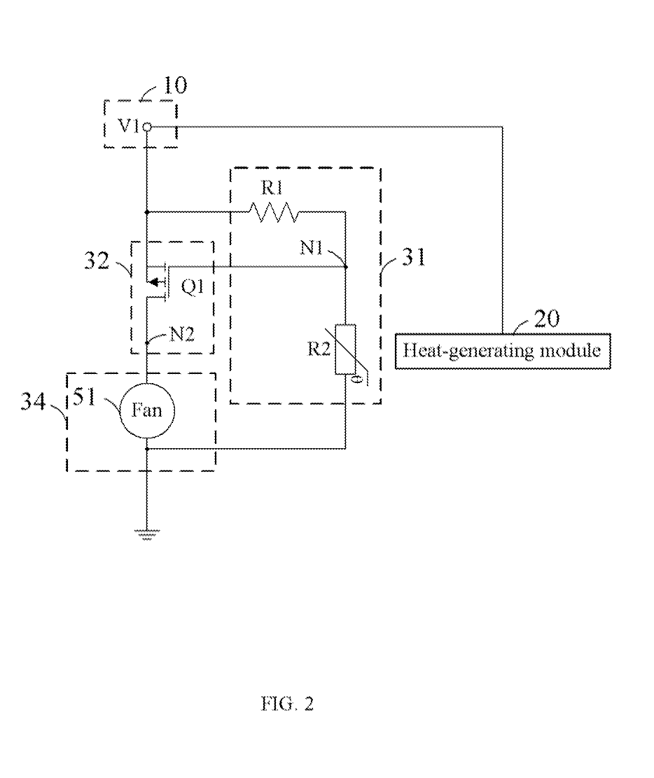

Referring to FIG. 2, the power supply 10 includes a power terminal V1 for providing the supply voltage.

The detecting module 31 includes a first resistor R1, a second resistor R2, and a first node N1. An end of the first resistor R1 is electrically connected to the power terminal V1, and the other end of the first resistor R1 is grounded through the first node and the second resistor R2. The resistance of the second resistor R2 is variable. In the embodiment, the second resistor R2 is a negative temperature coefficient thermistor.

The switching module 32 includes a transistor Q1 and a second node N2. A source of the transistor Q1 is electrically connected to the power terminal V1. A gate of the transistor Q1 is electrically connected to the first node N1. A drain of the transistor Q1 is electrically connected to the heat dissipation module 34 through the second node N2. In the embodiment, the transistor Q1 is a p-channel enhancement type metal oxide semiconductor field effect transistor.

The heat dissipation module 34 includes a fan 51. The positive power terminal of the fan 51 is electrically connected to the second node N2, the negative power terminal of the fan 51 is grounded.

When the electronic device 100 is powered on, the power terminal V1 outputs a supply voltage to the heat generating module 20 and the heat dissipation circuit 30. The heat of the heat generating module 20 is increased based on the supply voltage, and the resistance of the second resistor R2 and the voltage of the first node N1 are decreased. When the difference in voltage of the source and the gate of the transistor Q1 is smaller than 0V, the transistor Q1 turns on and output a working voltage to the fan 51. The resistance of the transistor Q1 decreased with the decreased voltage of the first node N1. The working voltage of the second node N2, the rotating speed of the fan 51 and the dissipation power of the fan 51 are increased.

When the heat of the heat generating module 20 is decreased by the fan 51, the resistance of the second resistor R2 is increased. The voltage of the first node N1 is increased to increase the resistance of the transistor Q1, and the voltage of the second node N2 is increased. Thus the rotating speed of the fan 51 and the dissipation power of the fan 51 are decreased. When the difference in voltage of the source and the gate of the transistor Q1 is equal to 0V, the transistor Q1 turns off and stops outputting a working voltage to the fan 51. The fan 51 stop rotating.

As described, the heat dissipation efficiency is linearly changed according to the variable heat. Therefore, the consumption of electrical energy is reduced.

It is to be understood, however, that even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device comprising:
a power supply;
a heat generating module adapted to being powered by the power supply to generate heat;
a detecting module adapted to detect the generated heat and generate a variable control voltage in response to the heat of the heat generating module;
a switching module presetting a predetermined voltage; and
a heat dissipation module adapted to dissipate the heat generated by the heat generating module;
wherein the switching module establishes the electrical connection between the power supply and the heat dissipation module when the control voltage is smaller than the predetermined voltage and outputs a variable working voltage; the dissipation module is powered by the working voltage to dissipate the heat of the heat generating module with different heat dissipation efficiency; the heat dissipation efficiency is variable with the working voltage.

2. The heat dissipation circuit of claim 1, wherein the heat dissipation efficiency is changed linearly with the working voltage; the when the working voltage is increased, the heat dissipation efficiency is also increased; when the working voltage is decreased, the heat dissipation efficiency is also decreased.

3. The heat dissipation circuit of claim 1, wherein the heat dissipation module is a fan, the heat dissipation module generates airflow towards the heat dissipation module to dissipate the heat of the heat generating module; the rotation speed of the heat dissipation module is variable with the working voltage.

4. The electronic device of claim 3, wherein the rotating speed of the heat dissipation is changed linearly with the working voltage.

5. The electronic device of claim 1, wherein the detecting module comprises a first resistor and a second resistor; the first resistor and the second resistor are electrically connected between the power supply and the ground in series; the resistance of the second resistor is adjustable.

6. The electronic device of claim 5, wherein the second resistor is a negative temperature coefficient thermistor.

7. The electronic device of claim 1, wherein the switching module comprises a transistor; a source of the transistor is electrically connected to the power supply, a gate of the transistor is electrically connected to the detecting module, a drain of the transistor is electrically connected to the heat dissipation module.

8. The electronic device of claim 7, wherein the transistor is a p-channel enhancement type metal oxide semiconductor field effect transistor.

9. A heat dissipation circuit powered by a power supply and adapted to dissipate heat generated by a heat generating module, the heat dissipation circuit comprising:
a detecting module adapted to detect the heat of the heat generating module and generate a control voltage variable with the heat of the heat generating module;
a switching module presetting a predetermined voltage; and
a heat dissipation module;
wherein the switching module establishes an electrical connection between the power supply and the heat dissipation module when the control voltage is smaller than the predetermined voltage and generate a working voltage variable with the control voltage;
the dissipation module is powered by the working voltage to dissipate the heat of the heat generating module with different heat dissipation efficiency; the heat dissipation efficiency is variable with the working voltage.

10. The heat dissipation circuit of claim 9, wherein the heat dissipation efficiency is changed linearly with the working voltage; when the working voltage is increased the heat dissipation efficiency is also increased; when the working voltage is decreased the heat dissipation efficiency is also decreased.

11. The heat dissipation circuit of claim 9, wherein the heat dissipation module is a fan, the heat dissipation module generates airflow towards the heat dissipation module to dissipate the heat of the heat generating module; the rotation speed of the heat dissipation module is variable with the working voltage.

12. The heat dissipation circuit of claim 11, wherein the rotating speed of the heat dissipation is changed linearly with the working voltage.

13. The heat dissipation circuit of claim 9, wherein the detecting module comprise a first resistor and a second resistor; the first resistor and the second resistor are electrically connected between the power supply and the ground in series; the resistance of the second resistor is adjustable.

14. The heat dissipation circuit of claim 13, wherein the second resistor is a negative temperature coefficient thermistor.

15. The heat dissipation circuit of claim 9, wherein the switching module comprises a transistor; a source of the transistor is electrically connected to the power supply, a gate of the transistor is electrically connected to the detecting module, a drain of the transistor is electrically connected to the heat dissipation module.

16. The heat dissipation circuit of claim 15, wherein the transistor is a p-channel enhancement type metal oxide semiconductor field effect transistor.
